(19) United States
(12) Patent Application Publication
(10) Pub. No.: US 2025/0167174 A1
(43) Pub. Date: May 22, 2025

(54) SEMICONDUCTOR PACKAGE AND METHOD OF IMPLEMENTING REDISTRIBUTION LAYER IN BALL GRID ARRAY

(71) Applicant: SAMSUNG ELECTRONICS CO., LTD., Suwon-si (KR)

(72) Inventors: Yunseok YANG, Suwon-si (KR); Yunsang Lee, Suwon-si (KR); Minsoo Kim, Suwon-si (KR); Jaewoo Shin, Suwon-si (KR); Minhwan An, Suwon-sii (KR); Yunkyeong Jeong, Suwon-si (KR); Jinsuk Chung, Suwon-si (KR)

(73) Assignee: SAMSUNG ELECTRONICS CO., LTD., Suwon-si (KR)

(21) Appl. No.: 18/737,484

(22) Filed: Jun. 7, 2024

(30) Foreign Application Priority Data
Nov. 22, 2023 (KR) 10-2023-0163100

(51) Int. Cl. H01L 25/065; H01L 23/00; H01L 23/28; H01L 23/48; H01L 23/498; H10B 80/00

(52) U.S. Cl. CPC H01L 25/0657; H01L 23/481; H01L 23/49816; H01L 23/49822; H01L 24/16; H10B 80/00; H01L 23/28; H01L 2224/16146; H01L 2224/16227; H01L 2225/06513

(57) ABSTRACT

A semiconductor package includes a plurality of first semiconductor chips sequentially stacked in a vertical direction, and connected to each other via a plurality of first through electrodes, each of the plurality of first semiconductor chips having a first width in a horizontal direction, a second semiconductor chip under the plurality of first semiconductor chips, and connected to the plurality of first semiconductor chips via a plurality of second through electrodes, the second semiconductor chip having a second width in the horizontal direction, the second width being greater than the first width, a redistribution layer under the second semiconductor chip, the redistribution layer having a third width in the horizontal direction, the third width being substantially equal to the second width, and a plurality of first connection bumps between the second semiconductor chip and the redistribution layer.

### CROSS-REFERENCE TO RELATED APPLICATION

This application is based on and claims priority under 35 U.S.C. § 119 to Korean Patent Application No. 10-2023-0163100 filed on Nov. 22, 2023 in the Korean Intellectual Property Office, the disclosure of which is incorporated by reference herein in its entirety.

### BACKGROUND

Example embodiments of the disclosure relate generally to semiconductor integrated circuits, and more particularly to semiconductor packages including stacked semiconductor chips or dies, and methods of manufacturing the semiconductor packages.

Semiconductor packages are becoming more compact while at the same time, performance such as capacity and speed are increasing. In a semiconductor system, a high bandwidth memory (HBM device may be utilized when relatively high bandwidth is required. A conventional HBM device may be implemented with uBumps, which are small in size and pitch, and a silicon interposer that is relatively expensive is used to mount the conventional HBM device. Thus, there may be a problem in that the manufacturing cost of the entire system is increased.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor package that may be capable of efficiently reducing system manufacturing costs.

One or more example embodiments further provide a method of manufacturing the semiconductor package.

Additional aspects will be set forth in part in the description which follows and, in part, will be apparent from the description, or may be learned by practice of the presented embodiments.

According to an aspect of an example embodiment, a semiconductor package includes: a plurality of first semiconductor chips sequentially stacked in a vertical direction, at least one of the plurality of first semiconductor chips including a plurality of first through electrodes connecting the plurality of first semiconductor chips to each other, each of the plurality of first semiconductor chips having a first width in a horizontal direction; a second semiconductor chip under the plurality of first semiconductor chips, the second semiconductor chips including a plurality of second through electrodes connecting the second semiconductor chip to the plurality of first semiconductor chips, the second semiconductor chip having a second width in the horizontal direction that is greater than the first width; a redistribution layer under the second semiconductor chip, the redistribution layer having a third width in the horizontal direction that is substantially equal to the second width; a plurality of first connection bumps between the second semiconductor chip and the redistribution layer, and connecting the second semiconductor chip with the redistribution layer, each of the plurality of first connection bumps having a first size; and a plurality of second connection bumps under the redistribution layer, and connecting the redistribution layer with an external device, each of the plurality of second connection bumps having a second size that is greater than the first size.

According to an aspect of an example embodiment, a semiconductor package includes: a first semiconductor device; a plurality of second semiconductor devices, wherein the first semiconductor device is configured to control the plurality of second semiconductor devices; and a connection substrate on which the first semiconductor device and the plurality of second semiconductor devices are provided, wherein each of the plurality of second semiconductor devices includes: a plurality of first semiconductor chips sequentially stacked in a vertical direction, at least one of the plurality of first semiconductor chips including a plurality of first through electrodes connecting the plurality of first semiconductor chips to each other, each of the plurality of first semiconductor chips having a first width in a horizontal direction; a second semiconductor chip under the plurality of first semiconductor chips, the second semiconductor chips including a plurality of second through electrodes connecting the second semiconductor chip to the plurality of first semiconductor chips, the second semiconductor chip having a second width in the horizontal direction that is greater than the first width; a redistribution layer under the second semiconductor chip, the redistribution layer having a third width in the horizontal direction that is substantially equal to the second width; a plurality of first connection bumps between the second semiconductor chip and the redistribution layer, and connecting the second semiconductor chip with the redistribution layer, each of the plurality of first connection bumps having a first size; and a plurality of second connection bumps under the redistribution layer, and connecting the redistribution layer with an external device, each of the plurality of second connection bumps having a second size that is greater than the first size.

According to an aspect of an example embodiment, a method of manufacturing a semiconductor package, includes: fabricating a plurality of first semiconductor chips and a second semiconductor chip, each of the plurality of first semiconductor chips have a first width in a horizontal direction, the second semiconductor chip having a second width in the horizontal direction that is greater than the first width; sequentially stacking the plurality of first semiconductor chips and the second semiconductor chip in a vertical direction, at least one of the plurality of first semiconductor chips including a plurality of first through electrodes connecting the plurality of first semiconductor chips to each other, the second semiconductor chips including a plurality of second through electrodes connecting the second semiconductor chip to the plurality of first semiconductor chips; forming a plurality of first connection bumps under the second semiconductor chip, each of the plurality of first connection bumps having a first size; forming a redistribution layer under the second semiconductor chip, the redistribution layer having a third width in the horizontal direction that is substantially equal to the second width; and forming a plurality of second connection bumps under the redistribution layer, each of the plurality of second connection bumps having a second size that is greater than the first size, wherein the plurality of first connection bumps and the plurality of second connection bumps are connected via the redistribution layer, wherein the second semiconductor chip and the redistribution layer are connected via the plurality of first connection bumps, and wherein the semiconductor package is connected to an external device via the plurality of second connection bumps.

According to an aspect of an example embodiment, a semiconductor package includes: a first dynamic random access memory (DRAM) chip having a first width in a horizontal direction; a plurality of second DRAM chips sequentially stacked in a vertical direction under the first DRAM chip, at least one of the plurality of second DRAM chips including a plurality of first through electrodes connecting the plurality of first semiconductor chips to each other and to the first DRAM chip, each of the plurality of second DRAM chips having a second width in the horizontal direction that is substantially equal to the first width; a buffer chip under the plurality of second DRAM chips, the buffer chip comprising a plurality of second through electrodes connecting to the first DRAM chip and the plurality of second DRAM chips, the buffer chip having a third width in the horizontal direction that is greater than the first width; a redistribution layer under the buffer chip, the redistribution layer having a fourth width in the horizontal direction that is substantially equal to the third width; a plurality of first connection bumps between the buffer chip and the redistribution layer, and connected to the plurality of second through electrodes and the redistribution layer, each of the plurality of first connection bumps having a first size; a plurality of second connection bumps under the redistribution layer, and connected to the redistribution layer, each of the plurality of second connection bumps having a second size that is greater than the first size; and an encapsulant encapsulating the first DRAM chip, the plurality of second DRAM chips and the buffer chip, the encapsulant covering side surfaces of the first DRAM chip, side surfaces of the plurality of second DRAM chips, and at least a portion of an upper surface of the buffer chip, wherein a number of the plurality of second connection bumps is less than a number of the plurality of first connection bumps, wherein a first number of first connection bumps among the plurality of first connection bumps are respectively connected to a second number of second connection bumps among the plurality of second connection bumps via the redistribution layer, wherein the first DRAM chip, the plurality of second DRAM chips and the buffer chip are electrically connected to an external device by the first number of first connection bumps, the redistribution layer and the second number of second connection bumps, and wherein a second number of first connection bumps among the plurality of first connection bumps are floated without connections with the redistribution layer, the plurality of second connection bumps and the external device.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view illustrating a semiconductor package according to one or more example embodiments:

FIGS. 2A, 2B, 2C and 3 are diagrams illustrating a semiconductor package according to one or more example embodiments:

FIGS. 4A, 4B, 4C, 4D and 4E are cross-sectional views illustrating a method of manufacturing a semiconductor package according to one or more example embodiments:

FIGS. 5, 6 and 7 are cross-sectional views illustrating a semiconductor package according to one or more example embodiments:

FIG. 8 is a perspective view illustrating a semiconductor package according to one or more example embodiments:

FIG. 9 is a block diagram illustrating a semiconductor system according to one or more example embodiments:

FIG. 10 is a block diagram illustrating an example of a memory chip included in a semiconductor system according to one or more example embodiments; and

FIG. 11 is a block diagram illustrating an electronic system according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

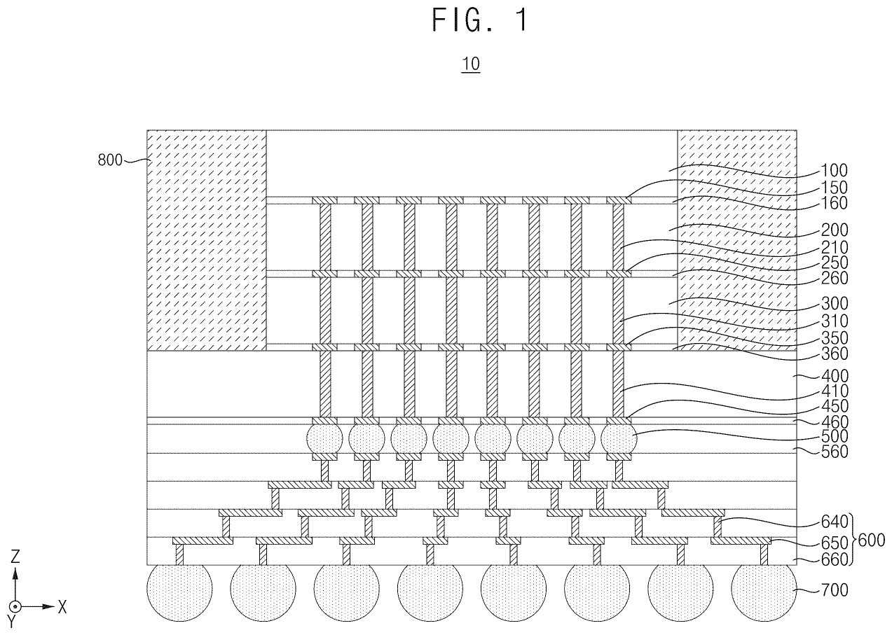

FIG. 1 is a cross-sectional view illustrating a semiconductor package according to one or more example embodiments.

In FIG. 1, two directions substantially parallel to a first surface (e.g., a top surface) of a substrate (e.g., a semiconductor substrate or a package substrate) and crossing each other are referred to as a first direction X (e.g., a first horizontal direction) and a second direction Y (e.g., a second horizontal direction). In addition, a direction substantially vertical to the first surface of the substrate is referred to as a third direction Z (e.g., a vertical direction). For example, the first and second directions X and Y may be substantially perpendicular to each other. For example, the third direction Z may be substantially perpendicular to both the first and second directions X and Y Further, a direction indicated by an arrow in the figures and a reverse direction thereof are considered as the same direction. The definition of the first, second and third directions X, Y and Z are same in the subsequent figures.

Referring to FIG. 1, a semiconductor package 10 may include a plurality of first semiconductor chips 100, 200 and 300, a second semiconductor chip 400, a plurality of first connection bumps 500, a redistribution layer 600 and a plurality of second connection bumps 700. The semiconductor package 10 may further include a plurality of connection structures 150, 250, 350 and 450, a plurality of insulating layers 160, 260, 360, 460 and 560, and an encapsulant 800. The semiconductor chip may be referred to as a semiconductor die, the connection bump may be referred to as a conductive bump, a solder bump, a solder ball or an electrical connection structure, and the encapsulant may be referred to as a sealing member.

The plurality of first semiconductor chips 100, 200 and 300 may be sequentially stacked in the vertical direction (e.g., in the third direction Z), and may be electrically connected to each other via a plurality of first through electrodes 210 and 310. For convenience of illustration, three first semiconductor chips 100, 200 and 300 are illustrated in FIG. 1, however, the number of the first semiconductor chips 100, 200 and 300 is not limited thereto. For example, the semiconductor package 10 may include two first semiconductor chips or four or more first semiconductor chips, which are stacked in the vertical direction.

In some example embodiments, at least some of the plurality of first semiconductor chips 100, 200 and 300 may include the plurality of first through electrodes 210 and 310. For example, the first semiconductor chip 200 may include the first through electrodes 210, and the first semiconductor chip 300 may include the first through electrodes 310. For example, the first semiconductor chip 100, which is the uppermost one among the plurality of first semiconductor chips 100, 200 and 300, may not include through electrodes. The first semiconductor chips 100 and 200 may be electrically connected via the first through electrodes 210, and the first semiconductor chips 200 and 300 may be electrically connected via the first through electrodes 310.

The second semiconductor chip 400 may be disposed or arranged under the plurality of first semiconductor chips 100, 200 and 300, and may be electrically connected to the plurality of first semiconductor chips 100, 200 and 300 via a plurality of second through electrodes 410. For example, the second semiconductor chip 400 may include the plurality of second through electrodes 410. For convenience of illustration, one second semiconductor chip 400 is illustrated in FIG. 1, however, the number of the second semiconductor chip 400 is not limited thereto. For example, the semiconductor package 10 may include two or more second semiconductor chips stacked in the vertical direction.

In some example embodiments, each of the plurality of first semiconductor chips 100, 200 and 300 may include a first semiconductor layer, and the second semiconductor chip 400 may include a second semiconductor layer. The plurality of first through electrodes 210 and 310 may penetrate the first semiconductor layer in the vertical direction (e.g., in the third direction Z), and the plurality of second through electrodes 410 may penetrate the second semiconductor layer in the vertical direction (e.g., in the third direction Z). For example, the first through electrodes 210 may be formed to penetrate the first semiconductor layer included in the first semiconductor chip 200, and the first through electrodes 310 may be formed to penetrate the first semiconductor layer included in the first semiconductor chip 300. For example, the plurality of first and second through electrodes 210, 310 and 410 may be through silicon vias (TSVs) formed by penetrating a silicon substrate.

The redistribution layer 600 may be disposed or arranged under the second semiconductor chip 400. For example, the redistribution layer 600 may include a plurality of vias 640, a plurality of wirings 650 and a plurality of insulating layers 660. The plurality of vias 640 and the plurality of wirings 650 may be used for redistributing or rewiring pads of the first and second semiconductor chips 100, 200, 300 and 400 or for electrical connections with the connection bumps 500 and 700. The plurality of insulating layers 660 may electrically insulate at least some of the plurality of wirings 650.

The plurality of first connection bumps 500 may be formed or disposed between the second semiconductor chip 400 and the redistribution layer 600, and may electrically connect the second semiconductor chip 400 with the redistribution layer 600. For example, the plurality of first connection bumps 500 may be or may include uBumps.

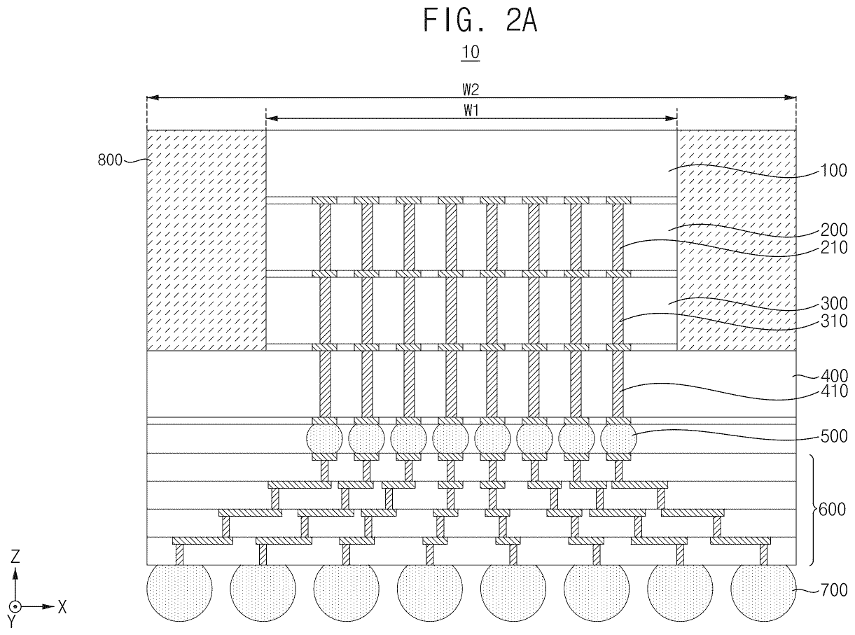

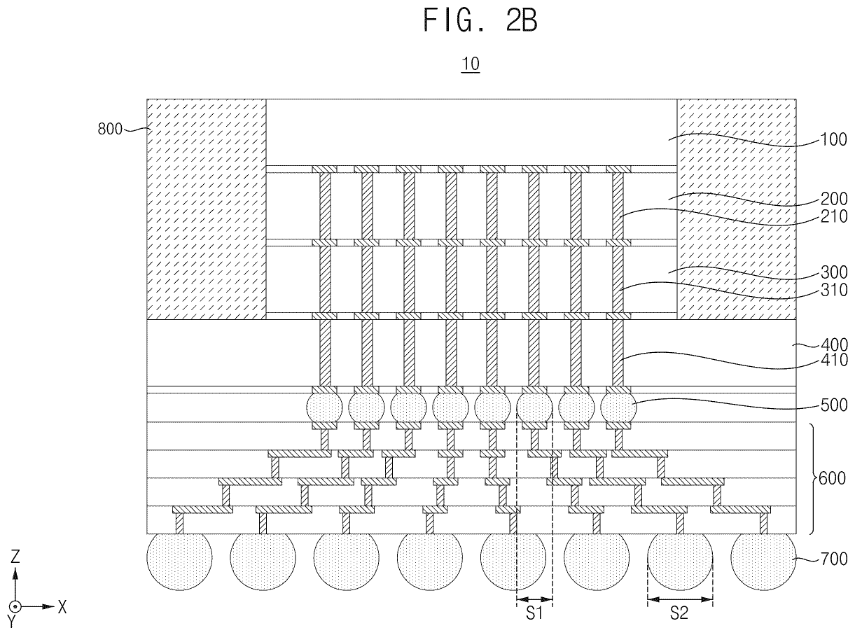

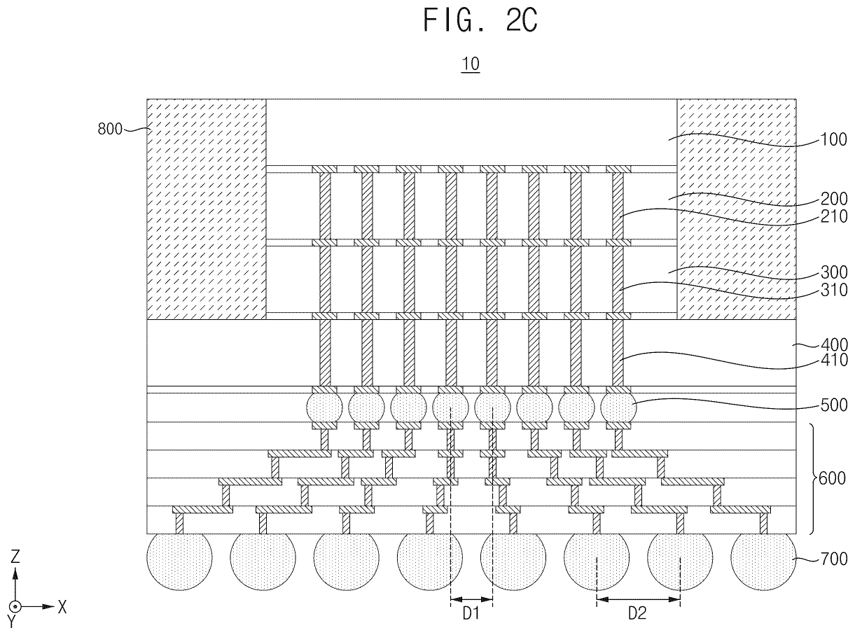

The plurality of second connection bumps 700 may be formed or disposed under the redistribution layer 600, and may electrically connect the redistribution layer 600 with an external device (e.g., another semiconductor package and/or another semiconductor device that are located outside the semiconductor package 10). For example, the plurality of second connection bumps 700 may be or may include bumps larger in size than the uBumps, which will be described with reference to FIG. 2B.

The plurality of first connection bumps 500 and the plurality of second connection bumps 700 may be electrically connected to each other by the redistribution layer 600. The first and second semiconductor chips 100, 200, 300 and 400 and the redistribution layer 600 may be electrically connected to each other by the plurality of first connection bumps 500. The semiconductor package 10 (e.g., the first and second semiconductor chips 100, 200, 300 and 400 and the redistribution layer 600) may be electrically connected to the external device by the plurality of second connection bumps 700.

In some example embodiments, the number of the plurality of second connection bumps 700 may be equal to the number of the plurality of first connection bumps 500. For example, the plurality of first connection bumps 500 may be respectively and electrically connected to the plurality of second connection bumps 700 via the redistribution layer 600. For convenience of illustration, eight first connection bumps 500 and eight second connection bumps 700 are illustrated in FIG. 1, however, the number of first connection bumps 500 and the number of second connection bumps 700 are not limited thereto.

The connection structures 150 may be electrically connected to the first through electrodes 210 such that the first semiconductor chips 100 and 200 are electrically connected to each other by the connection structures 150, and the insulating layer 160 may electrically insulate the connection structures 150. The connection structures 250 may be electrically connected to the first through electrodes 210 and 310 such that the first semiconductor chips 200 and 300 are electrically connected to each other by the connection structures 250, and the insulating layer 260 may electrically insulate the connection structures 250. The connection structures 350 may be electrically connected to the first and second through electrodes 310 and 410 such that the first and second semiconductor chips 300 and 400 are electrically connected to each other by the connection structures 350, and the insulating layer 360 may electrically insulate the connection structures 350. The connection structures 450 may be electrically connected to the second through electrodes 410 and the second connection bumps 700 such that the second semiconductor chip 400 and the second connection bumps 700 are electrically connected to each other by the connection structures 450, and the insulating layer 460 may electrically insulate the connection structures 450. The insulating layer 560 may electrically insulate the second connection bumps 700.

In some example embodiments, when the plurality of first connection bumps 500 are formed between the second semiconductor chip 400 and the redistribution layer 600, the second semiconductor chip 400 and the redistribution layer 600 may be spaced apart from each other in the vertical direction (e.g., in the third direction Z). In other words, a lower surface of the second semiconductor chip 400 (e.g., the connection structures 450 and the insulating layer 460) and an upper surface of the redistribution layer 600 may be spaced apart from each other by a certain distance. An air layer may be formed between the second semiconductor chip 400 and the redistribution layer 600, rather than the insulating layer 560 that electrically insulates the second connection bumps 700.

The encapsulant 800 may encapsulate or seal the plurality of first semiconductor chips 100, 200 and 300 and the second semiconductor chip 400. For example, the encapsulant 800 may be formed to expose an upper surface of the first semiconductor chip 100 that is the uppermost one among the plurality of first semiconductor chips 100, 200 and 300. For example, the encapsulant 800 may directly contact side surfaces of the plurality of first semiconductor chips 100, 200 and 300 and directly contact at least a portion of an upper surface of the second semiconductor chip 400. For example, an upper surface of the semiconductor package 10 may be formed by an upper surface of the encapsulant 800 and the upper surface of the first semiconductor chip 100. However, example embodiments are not limited thereto.

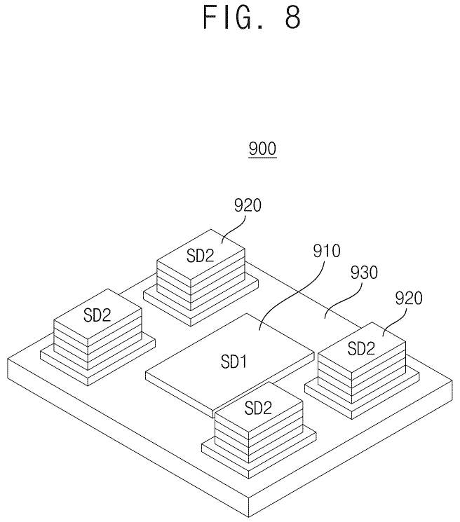

In some example embodiments, the plurality of first semiconductor chips 100, 200 and 300 and the second semiconductor chip 400 may be different types of semiconductor chips. For example, as will be described with reference to FIGS. 8, 9 and 10, the plurality of first semiconductor chips 100, 200 and 300 may be or may include memory chips (e.g., dynamic random access memory (DRAM) chips) that store data, the second semiconductor chip 400 may be a buffer chip that controls operations of the memory chips, and the semiconductor package 10 may be a high bandwidth memory (HBM) device. However, example embodiments are not limited thereto.

Although the upper portion (or top portion), lower portion (or bottom portion), upper surface (or top surface), lower surface (or bottom surface), etc. are described based on the structure of the semiconductor package 10 illustrated in FIG. 1, example embodiments are not limited thereto. For example, when the semiconductor package 10 is turned over during the manufacturing process, the above-described upper and lower portions may be reversed, and the above-mentioned upper and lower surfaces may be reversed.

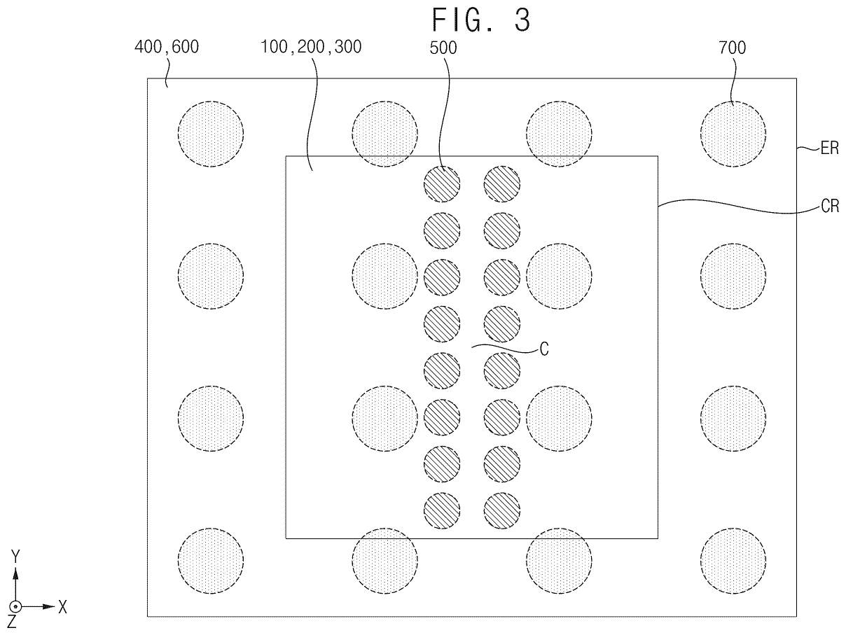

FIGS. 2A, 2B, 2C and 3 are diagrams illustrating a semiconductor package according to one or more example embodiments. The descriptions repeated with or overlapping with descriptions of FIG. 1 may be omitted in the interest of brevity.

Referring to FIG. 2A, each of the plurality of first semiconductor chips 100, 200 and 300 may have a first width W1 in a horizontal direction (e.g., in the first direction X), the second semiconductor chip 400 may have a second width W2 that is greater than the first width W1 in the horizontal direction (e.g., in the first direction X), and the redistribution layer 600 may have the second width W2 in the horizontal direction (e.g., in the first direction X). In other words, the second semiconductor chip 400 and the redistribution layer 600 may have the same width in the horizontal direction, and the plurality of first semiconductor chips 100, 200 and 300 may have widths smaller than the widths of the second semiconductor chip 400 and the redistribution layer 600 in the horizontal direction.

A size of the semiconductor package 10 may be determined as the second width W2, which represents sizes of the second semiconductor chip 400 and the redistribution layer 600. In this example, the size of the semiconductor package 10 may not be increased and may be maintained even if the redistribution layer 600 is additionally formed or disposed.

Although FIG. 2A illustrates an example where the horizontal direction is the first direction X, example embodiments are not limited thereto. For example, each of the plurality of first semiconductor chips 100, 200 and 300 may have a first length in the second direction Y, and each of the second semiconductor chip 400 and the redistribution layer 600 may have a second length greater than the first length in the second direction Y In this example, the size of the semiconductor package 10 may be determined as the second length, which represents the sizes of the second semiconductor chip 400 and the redistribution layer 600.

Referring to FIG. 2B, each of the plurality of first connection bumps 500 may have a first size S1, and each of the plurality of second connection bumps 700 may have a second size S2 that is greater than the first size S1. In other words, the plurality of first connection bumps 500 may be smaller in size than the plurality of second connection bumps 700. For example, the first size S1 may be a diameter of each of the plurality of first connection bumps 500, and the second size S2 may be a diameter of each of the plurality of second connection bumps 700. Although the first size S1 and the second size S2 are shown as horizontal widths in FIG. 2B, the sizes S1 and S2 are not limited thereto, and the first size S1 and second size S2 may refer to widths of the bumps, heights of the bumps, areas of the bumps, as well as other parameters that would indicate a difference in size. For example, each of the first size S1 and the second size S2 may be represented as a radius, an area, etc.

In some example embodiments, the first size S1 may be greater than about 1 um and less than or equal to about 25 um. In some example embodiments, the second size S2 may be greater than about 25 um.

Referring to FIG. 2C, a distance between two adjacent connection bumps of the plurality of first connection bumps 500 may be a first distance D1, and a distance between two adjacent connection bumps of the plurality of second connection bumps 700 may be a second distance D2 that is longer than the first distance D1. In other words, a distance between adjacent first connection bumps 500 may be less than a distance between adjacent second connection bumps 700. For example, the first distance D1 may be a distance between centers of two adjacent connection bumps of the first connection bumps 500, and the second distance D2 may be a distance between centers of two adjacent connection bumps of the second connection bumps 700, although other reference points between adjacent connection bumps may be utilized to indicate variances in distances. Each of the first distance D1 and the second distance D2 may be referred to as a pitch.

In some example embodiments, the first distance D1 may be greater than about 1 um and less than or equal to about 55 um. In some example embodiments, the second distance D2 may be greater than about 55 um.

As described with reference to FIGS. 2B and 2C, when using the second connection bumps 700 where the size is larger than the first connection bumps 500 and the distance between adjacent bumps is greater than the first connection bumps 500, the electrical connection between the semiconductor package 10 and the external device may be relatively easily implemented.

Referring to FIG. 3, in a plan view or on a plane, the plurality of first connection bumps 500 may be arranged adjacent to a center C of the semiconductor package 10, and the plurality of second connection bumps 700 may be arranged regularly or uniformly in the entire region (e.g., the second region ER) of the semiconductor package 10.

For example, the plurality of first connection bumps 500 may be disposed in a first region CR where the plurality of first semiconductor chips 100, 200 and 300 are formed. For example, the plurality of first connection bumps 500 may be arranged within a relatively narrow first range in the first direction X and within a relatively wide second range in the second direction Y As shown in FIG. 3, in some embodiments, in the first region CR, the plurality of connection bumps 500 may be arranged such that a greater number of connection bumps extend along the vertical direction (the Y direction) and a fewer number of connection bumps extend along the horizontal direction (the X direction). As shown in FIG. 3, the plurality of connection bumps 500 may be arranged in two columns and eight rows. However, example embodiments are not limited thereto, and the arrangement of the plurality of first connection bumps 500 in the first region may be variously determined according to example embodiments. Alternatively, some of the plurality of first connection bumps 500 may be disposed in a region other than the first region CR (e.g., a region ER surrounding the first region).

For example, the plurality of second connection bumps 700 may be disposed in a second region ER where the second semiconductor chip 400 and the redistribution layer 600 are formed. For example, in a plan view or on a plane, the first region CR may be included in the second region ER. For example, the plurality of second connection bumps 700 may be uniformly disposed at regular distances in the first direction X and the second direction Y That is, the plurality of second connection bumps 700 may be arranged around the second region ER and spaced apart by equal or substantially equal distances both vertically and horizontally in the plan view. When the plurality of second connection bumps 700 are arranged regularly or uniformly, the semiconductor package 10 and the external device may be electrically connected stably without deviation or bias.

The semiconductor package according to example embodiments may include the redistribution layer 600 for redistributing the plurality of first connection bumps 500, and may include the plurality of second connection bumps 700 formed under the redistribution layer 600. The second semiconductor chip 400 and the redistribution layer 600 may have the same or substantially the same width in the horizontal direction, and thus the footprint of the semiconductor package 10 may not be increased and may be maintained. In addition, each of the second connection bumps 700 may have the second size S2 that is greater than that of each of the first connection bumps 500, and the distance between two adjacent second connection bumps 700 may be greater than that between two adjacent first connection bumps 500. Thus, the electrical connection between the semiconductor package 10 and the external device may be relatively easily implemented. Accordingly, the semiconductor package 10 may be mounted on an interposer or a package substrate that is relatively inexpensive, and the manufacturing cost of a system including the semiconductor package 10 may be efficiently reduced.

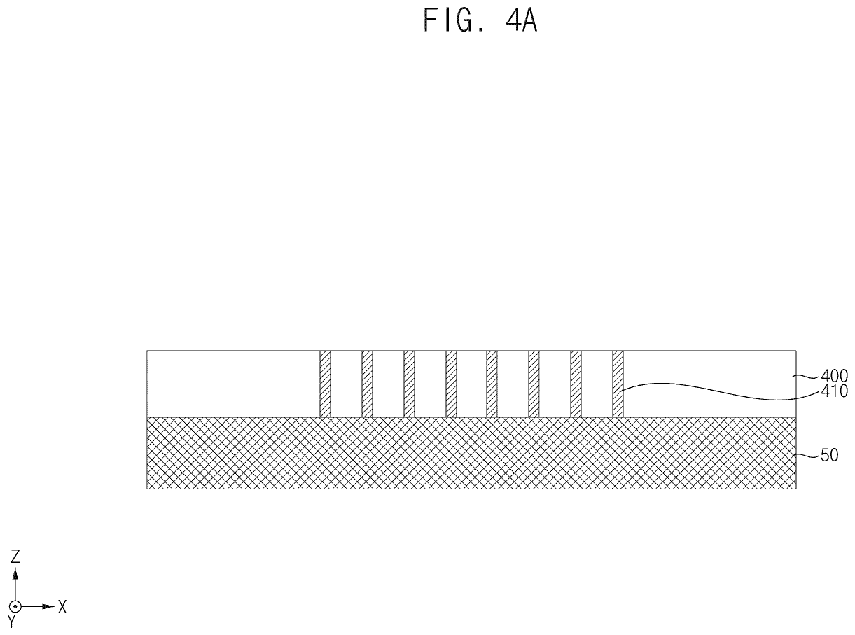

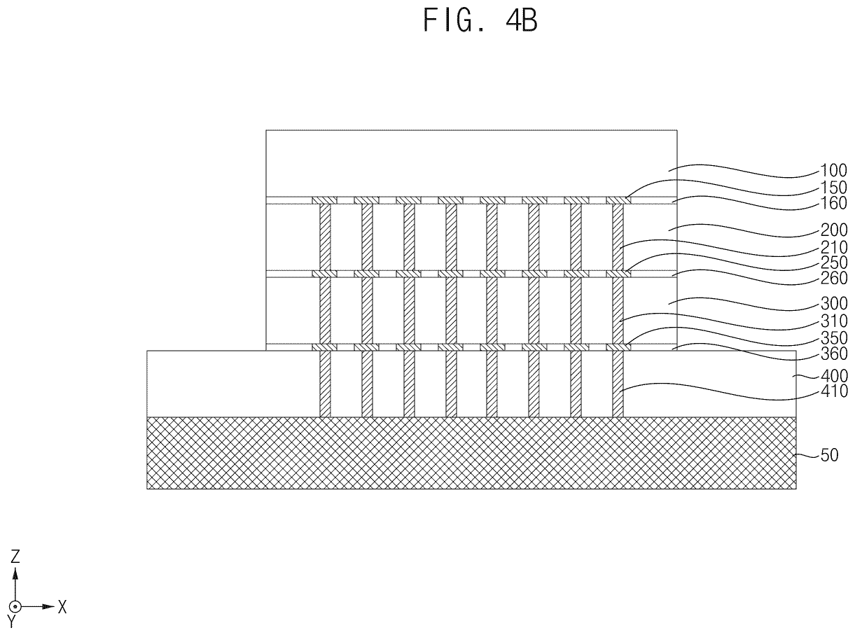

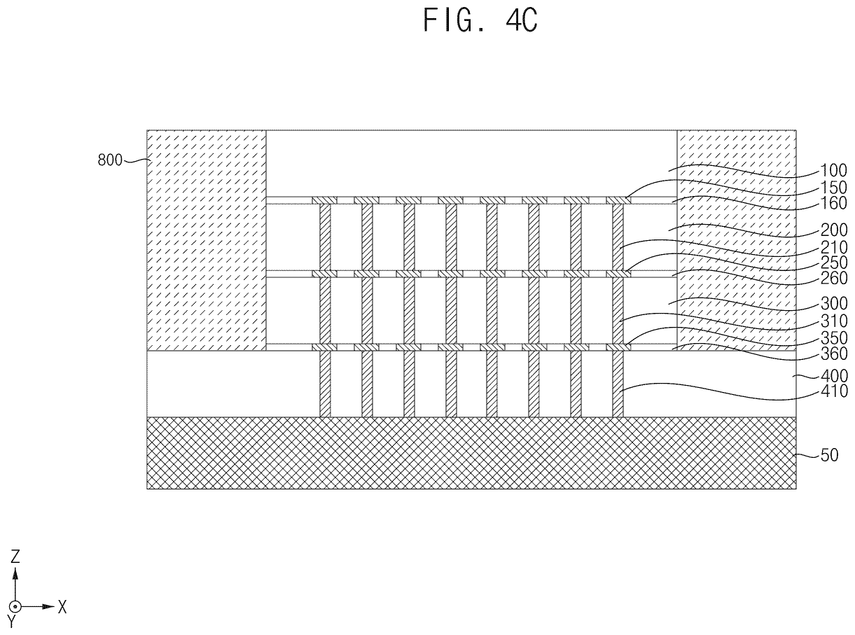

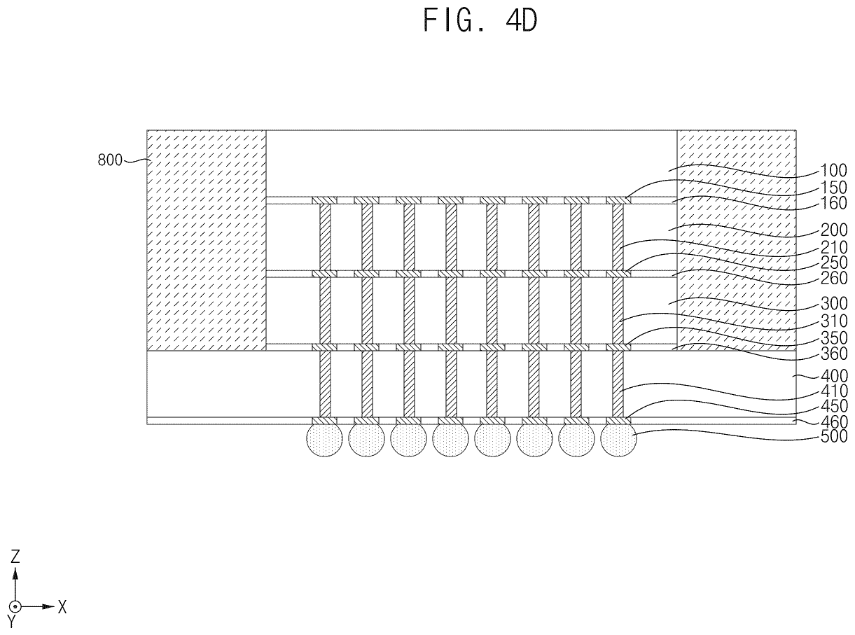

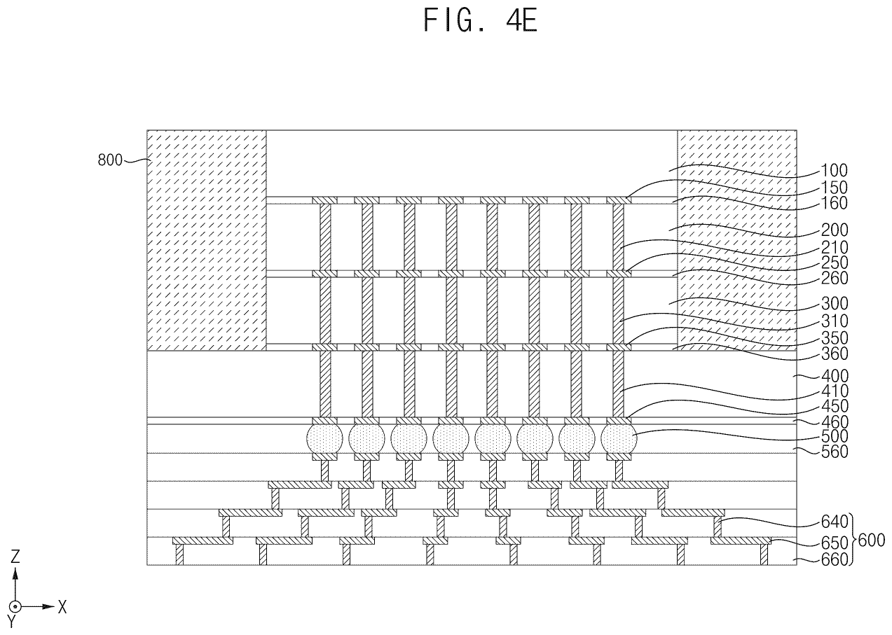

FIGS. 4A, 4B, 4C, 4D and 4E are cross-sectional views illustrating a method of manufacturing a semiconductor package according to one or more example embodiments.

Referring to FIG. 4A, the second semiconductor chip 400 including the plurality of second through electrodes 410 formed by penetrating the second semiconductor chip 400 may be fabricated or manufactured, and a carrier 50 may be attached to a lower portion of the second semiconductor chip 400.

In some example embodiments, the second semiconductor chip 400 may include a semiconductor element such as silicon or germanium (Ge), and/or may include a compound semiconductor such as silicon carbide (SiC), gallium arsenide (GaAs), indium arsenide (InAs) or indium phosphide (InP). For example, the second semiconductor chip 400 may have a silicon on insulator (SOI) structure. For example, the second semiconductor chip 400 may include a conductive region (e.g., a well which is doped with an impurity or a structure which is doped with an impurity). For example, the second semiconductor chip 400 may include various element isolation structures such as a shallow trench isolation (STI) structure.

In some example embodiments, the second semiconductor chip 400 may include various types of active elements and/or passive elements. For example, the second semiconductor chip 400 may include a field effect transistor (FET) such as a planar FET or a FinFET, a logic element such as an AND, an OR or a NOT, a system large scale integration (LSI), a complementary metal oxide semiconductor (CMOS) imaging sensor (CIS), a micro-electro-mechanical system (MEMS), etc.

In some example embodiments, the second semiconductor chip 400 may include an interlayer insulating layer and a multilayer wiring layer on the above-described elements. For example, the interlayer insulating layer may include silicon oxide or silicon nitride. For example, the multilayer wiring layer may include a multilayer wiring and/or a vertical contact. For example, the multilayer wiring layer may connect the elements of the second semiconductor chip 400 to each other, may connect the elements to a conductive region of the second semiconductor chip 400, and/or may connect the elements to the second through electrodes 410 and/or the pads.

In some example embodiments, a plurality of through holes penetrating the second semiconductor chip 400 may be formed, and the plurality of second through electrodes 410 may be formed in the plurality of through holes. For example, the plurality of through holes may be formed using a mechanical drill, a laser drill, or the like. For example, the plurality of second through electrodes 410 may be formed by a plating process. For example, the plating process may be a subtractive process, an additive process, a semi-additive process (SAP), a modified semi-additive process (MSAP), or the like.

In some example embodiments, materials of the plurality of second through electrodes 410 may be a conductive material such as copper (Cu), aluminum (Al), silver (Ag), tin (Sn), gold (Au), nickel (Ni), lead (Pb), titanium (Ti), and/or alloys thereof. For example, each of the plurality of second through electrodes 410 may be entirely filled with the conductive material, or the conductive material may be formed along a wall of respective one of the plurality of through holes. In addition, each of the plurality of second through electrodes 410 may have any known shape such as an hourglass shape, a cylindrical shape, and the like.

In some example embodiments, each of the plurality of second through electrodes 410 may include a conductive plug and a barrier layer surrounding the conductive plug. For example, the conductive plug may include a metal material, e.g., tungsten (W), titanium (Ti), aluminum (Al) and/or copper (Cu). For example, the conductive plug may be formed by a plating process, a physical vapor deposition (PVD) process or a chemical vapor deposition (CVD) process. For example, the barrier layer may include an insulating barrier layer and/or a conductive barrier layer. For example, the insulating barrier layer may be formed of an oxide film, a nitride film, a carbide film, a polymer, and/or a combination thereof. For example, the conductive barrier layer may be disposed between the insulating barrier layer and the conductive plug. For example, the conductive barrier layer may include, e.g., a metal compound such as tungsten nitride (WN), titanium nitride (TiN) and/or tantalum nitride (TaN). For example, the barrier layer may be formed by a PVD process or a CVD process.

In some example embodiments, the carrier 50 may include a support substrate, and an adhesive material for attaching the second semiconductor chip 400 to the support substrate.

In some example embodiments, the second semiconductor chip 400 may be fabricated first, and then the carrier 50 may be attached to the second semiconductor chip 400. However, example embodiments are not limited thereto.

Referring to FIG. 4B, the plurality of first semiconductor chips 100, 200 and 300 including the plurality of first through electrodes 210 and 310 formed by penetrating the first semiconductor layers may be fabricated or manufactured, and the plurality of first semiconductor chips 100, 200 and 300 may be stacked on the second semiconductor chip 400.

The first semiconductor chips 100, 200 and 300, and the plurality of first through electrodes 210 and 310 may have characteristics which are substantially the same as or similar to those of the second semiconductor chip 400 and the plurality of second through electrodes 410, respectively, and thus redundant descriptions thereof may be omitted. For example, the first semiconductor chips 100, 200 and 300 may include a memory element such as a DRAM, a static random access memory (SRAM), an electrically erasable programmable read-only memory (EEPROM), a phase-change random access memory (PRAM), a resistive random access memory (RRAM), a magnetic random access memory (MRAM), a ferroelectric random access memory (FRAM), etc.

In some example embodiments, the connection structures 150, 250 and 350 may be formed by a reflow process, or the like, and then the plurality of first semiconductor chips 100, 200 and 300 and the second semiconductor chip 400 may be electrically connected to each other via the connection structures 150, 250 and 350. For example, the connection structures 150, 250 and 350 may include tin (Sn) or an alloy containing tin (e.g., Sn—Ag—Cu). For example, the connection structures 150, 250 and 350 may be micro bumps that are smaller than the first connection bumps 500.

In some example embodiments, the plurality of first semiconductor chips 100, 200, and 300 and the second semiconductor chip 400 may be stacked using a bonding scheme. For example, pads may be formed on a lower surface of the first semiconductor chip 100 and an upper surface of the first semiconductor chip 200, and then the first semiconductor chips 100 and 200 may be stacked by electrically or physically connecting the pads to each other. For example, the pads may be formed of copper (Cu), and the bonding scheme may be a Cu—Cu bonding scheme. In addition, the first semiconductor chips 200 and 300 may be stacked in the same manner, and the first and second semiconductor chips 300 and 400 may be stacked in the same manner.

In some example embodiments, the insulating layers 160, 260 and 360 may include an insulating material such as silicon oxide. In some example embodiments, the insulating layers 160, 260 and 360 may further include an adhesive material such as an epoxy material. For example, the adhesive material may be underfilled between the plurality of first semiconductor chips 100, 200 and 300 and the second semiconductor chip 400 to reinforce gaps between the plurality of first semiconductor chips 100, 200 and 300 and the second semiconductor chip 400.

In some example embodiments, the plurality of first semiconductor chips 100, 200 and 300 may be sequentially stacked first, and then the plurality of first semiconductor chips 100, 200 and 300 may be stacked on the second semiconductor chip 400. In other example embodiments, the plurality of first semiconductor chips 100, 200 and 300 may be sequentially stacked on the second semiconductor chip 400. However, example embodiments are not limited thereto.

Referring to FIG. 4C, the encapsulant 800 for encapsulating the plurality of first semiconductor chips 100, 200 and 300 and the second semiconductor chip 400 may be formed. The encapsulant 800 may encapsulate or protect the plurality of first semiconductor chips 100, 200 and 300 and the second semiconductor chip 400, and may provide an insulating region.

In some example embodiments, the encapsulant 800 may include an insulating material. For example, the insulating material may be a thermosetting resin such as an epoxy resin, a thermoplastic resin such as a polyimide resin, a resin in which the thermosetting resin or the thermoplastic resin is impregnated together with an inorganic filler in a core material such as a glass fiber (or a glass cloth or a glass fabric). For example, the insulating material may be prepreg, Ajinomoto Build up Film (ABF), FR-4, Bismaleimide Triazine (BT), and/or the like. Alternatively, a material of the encapsulant 800 is not particularly limited, but may be, for example, a photoimagable encapsulant (PIE).

In some example embodiments, an encapsulation form of the encapsulant 800 is not particularly limited. For example, as illustrated in FIG. 4C, the encapsulant 800 may cover the side surfaces of the first semiconductor chips 100, 200 and 300 and at least a portion of the upper surface of the second semiconductor chip 400. For example, the encapsulant 800 may be formed to expose the upper surface of the first semiconductor chip 100 that is the uppermost one among the plurality of first semiconductor chips 100, 200 and 300. For example, by a planarization process, an upper surface of the encapsulant 800 may be substantially coplanar with the upper surface of the first semiconductor chip 100. For example, the planarization process may be performed by a chemical mechanical polishing (CMP) process.

Referring to FIG. 4D, the carrier 50 may be removed, and the plurality of first connection bumps 500 may be formed under the second semiconductor chip 400.

The connection structures 450 and the insulating layer 460 between the second semiconductor chip 400 and the plurality of first connection bumps 500 may have characteristics which are substantially the same as or similar to those of the connection structures 150, 250 and 350 and the insulating layers 160, 260 and 360, respectively, and thus redundant descriptions thereof may be omitted.

In some example embodiments, the plurality of first connection bumps 500 may be formed of a conductive material, such as a solder, or the like. However, example embodiments are not limited thereto, and materials of each of the plurality of first connection bumps 500 may vary. For example, the plurality of first connection bumps 500 may be a land, a ball, a pin, and/or the like. For example, the plurality of first connection bumps 500 may be formed as a multilayer or single layer structure. In an example in which the first connection bumps 500 are formed as a multilayer structure, the first connection bumps 500 may include a copper (Cu) pillar and a solder. In an example in which the first connection bumps 500 are formed as a single layer structure, the first connection bumps 500 may include a tin-silver solder, copper (Cu), and/or the like. However, this is only an example, and the first connection bumps 500 are not limited thereto. For example, the number, an interval, a disposition form, and the like, of the plurality of first connection bumps 500 are not particularly limited, but may be sufficiently modified depending on design particulars by those skilled in the art.

Referring to FIG. 4E, the redistribution layer 600 may be formed under the second semiconductor chip 400 and the plurality of first connection bumps 500.

The insulating layer 560 between the second semiconductor chip 400 and the redistribution layer 600 may have characteristics which are substantially the same as or similar to those of the insulating layers 160, 260, 360 and 460, and thus redundant descriptions thereof may be omitted.

In some example embodiments, the uppermost insulating layer among the plurality of insulating layers 660 in the redistribution layer 600 may be formed by a lamination process or any known application process. Via-holes may then be formed in the uppermost insulating layer by a photolithography process. For example, some of the vias 640 and some of the wirings 650 in or on the uppermost insulating layer may then be formed by a plating process. In a similar manner, the remaining of the insulating layers 660, the remaining of the vias 640 and the remaining of the wirings 650 may then be sequentially formed.

In some example embodiments, the plurality of insulating layers 660 may include an insulating material. For example, the insulating material may be a thermosetting resin such as an epoxy resin, a thermoplastic resin such as a polyimide resin, a resin in which the thermosetting resin or the thermoplastic resin is impregnated together with an inorganic filler in a core material such as a glass fiber. For example, the insulating material may be prepreg, ABF, FR-4, BT, and/or the like.

In some example embodiments, at least portions of the plurality of insulating layers 660 may include a photosensitive insulating material such as a photoimagable dielectric (PID) resin. For example, at least portions of the plurality of insulating layers 660 may be a photosensitive insulating layer. In an example in which the insulating layer 660 has photosensitive properties, the insulating layer 660 may be formed to have a lower thickness, and a fine pitch of the vias 640 may be achieved more easily. For example, the insulating layer 660 may be a photosensitive insulating layer including an insulating resin and an inorganic filler. In an example in which the insulating layers 660 are multiple layers, materials of the insulating layers 660 may be the same as each other or may also be different from each other. In an example in which the insulating layers 660 are the multiple layers, the insulating layers 660 may be integrated with each other depending on a process, such that a boundary therebetween may also not be apparent.

In some example embodiments, the lowermost insulating layer among the plurality of insulating layers 660 may be a passivation layer. The passivation layer may protect the semiconductor package 10 from external physical and/or chemical damages. For example, the passivation layer may include an insulating resin and an inorganic filler, but may not include a glass fiber. For example, the passivation layer may be formed of an ABF. However, example embodiments of the passivation layer are not limited thereto. For example, the passivation layer may also be formed of a PID, a solder resist, and/or the like. For example, the passivation layer may be formed by any known lamination process, hardening process, or the like.

In some example embodiments, the plurality of vias 640 and the plurality of wirings 650 may include a conductive material such as copper (Cu), aluminum (Al), silver (Ag), tin (Sn), gold (Au), nickel (Ni), lead (Pb), titanium (Ti), and/or alloys thereof. For example, each of the plurality of vias 640 may be a filled via formed by filling a via hole with a metal material or a conformal via in which a metal material is formed on an inner wall of the via hole.

In some example embodiments, the redistribution layer 600 may perform various functions depending on a design. For example, the redistribution layer 600 may include ground patterns, power patterns and signal patterns. The signal patterns may include communication paths for transmitting various signals, e.g., data signals, etc., other than the ground patterns and the power patterns.

Thereafter, the plurality of second connection bumps 700 may be formed under the redistribution layer 600, and thus the manufacturing process of the semiconductor package 10 may be completed.

Although FIGS. 4A, 4B, 4C, 4D and 4E illustrate a process of manufacturing one semiconductor package 10, example embodiments are not limited thereto. For example, when one semiconductor package 10 includes three first semiconductor chips 100, 200 and 300 as illustrated, a plurality of first semiconductor chips 100 may be fabricated at once (or at one time) on a single wafer, a plurality of first semiconductor chips 200 may be fabricated at once on a single wafer, a plurality of first semiconductor chips 300 may be fabricated at once on a single wafer, a plurality of second semiconductor chips 400 may be fabricated at once on a single wafer, a plurality of semiconductor packages 10 may be manufactured at once using four wafers by a series of processes described with reference to FIGS. 4A, 4B, 4C, 4D and 4E, and then the plurality of semiconductor packages 10 may be separated into individual semiconductor package 10 by a sawing process.

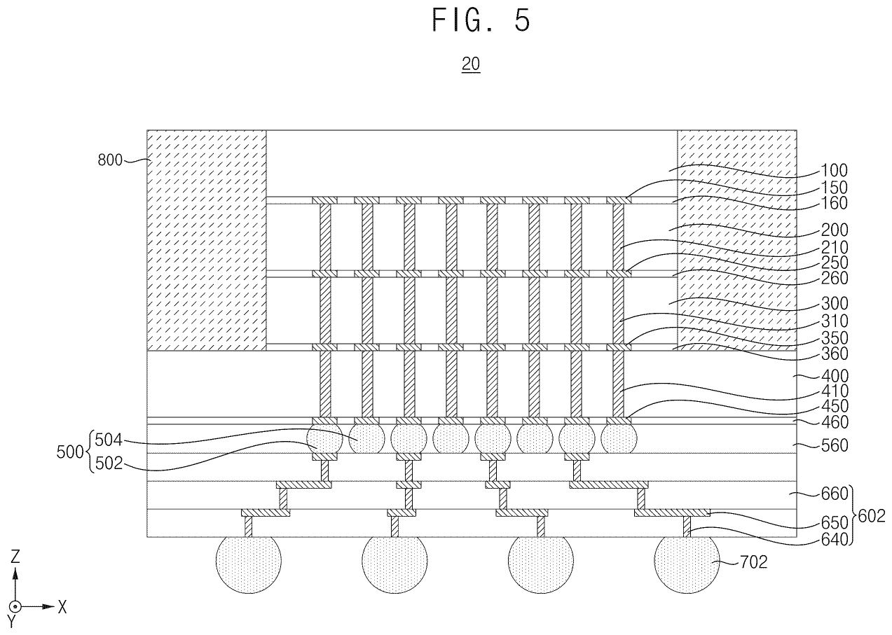

FIGS. 5, 6 and 7 are cross-sectional views illustrating a semiconductor package according to example embodiments. The descriptions of aspects the same as or similar to aspects of FIG. 1 may be omitted in the interest of brevity.

Referring to FIG. 5, a semiconductor package 20 may include a plurality of first semiconductor chips 100, 200 and 300, a second semiconductor chip 400, a plurality of first connection bumps 500, a redistribution layer 602 and a plurality of second connection bumps 702. The semiconductor package 20 may further include a plurality of connection structures 150, 250, 350 and 450, a plurality of insulating layers 160, 260, 360, 460 and 560, and an encapsulant 800.

The semiconductor package 20 may be substantially the same as the semiconductor package 10 of FIG. 1, except that configurations of the redistribution layer 602 and the plurality of second connection bumps 702 are partially changed.

In some example embodiments, the number of the plurality of second connection bumps 702 may be less than the number of the plurality of first connection bumps 500. For example, the number of the plurality of first connection bumps 500 may be twice the number of the plurality of second connection bumps 702. In other words, the number of the plurality of second connection bumps 702 may be a half of the number of the plurality of first connection bumps 500.

In some example embodiments, the plurality of first connection bumps 500 may include first connection bumps 502 and second connection bumps 504. The first connection bumps 502 of the plurality of first connection bumps 500 may be respectively and electrically connected the plurality of second connection bumps 702 via the redistribution layer 602. The second connection bumps 504 of the plurality of first connection bumps 500 may be floated without electrical connections with the plurality of second connection bumps 702. The redistribution layer 602 may be implemented to respectively and electrically connect the first connection bumps 502 of the plurality of first connection bumps 500 with the plurality of second connection bumps 702. As shown in FIG. 5, the number of first connection bumps 502 may be four, and there may be four second connection bumps 702, such that the first connection bumps 502 are respectively (i.e., one to one) connected to the second connection bumps 702. Furthermore, the number of second connection bumps 504 may be four, and these connection bumps 504 may be floated without electrical connections with the plurality of second connection bumps 702. Thus, with the plurality of connection bumps 500, the connection bumps 502 that are connected to connection bumps 702 and the connection bumps 504 that are floated without electrical connections with the plurality of second connection bumps 702 may alternate.

In some example embodiments, the first connection bumps 502 of the plurality of first connection bumps 500 may be odd-numbered connection bumps among the plurality of first connection bumps 500, and the second connection bumps 504 of the plurality of first connection bumps 500 may be even-numbered connection bumps among the plurality of first connection bumps 500.

In some example embodiments, the semiconductor package 20 may be a HBM device, and the plurality of first connection bumps 500 and the plurality of second connection bumps 702 may be electrically connected to data input/output (I/O) pads of the plurality of first semiconductor chips 100, 200 and 300, which are DRAM chips. For example, the plurality of first connection bumps 500 may include first data I/O bumps electrically connected to the data I/O pads, the plurality of second connection bumps 702 may include second data I/O bumps electrically connected to the data I/O pads, and the number of the first data I/O bumps and the number of the second data I/O bumps may be 1024 and 512, respectively.

However, example embodiments are not limited thereto. For example, the plurality of first connection bumps 500 and the plurality of second connection bumps 702 may include first address bumps and second address bumps, respectively, that are connected to address pads of the plurality of first semiconductor chips 100, 200 and 300, and the number of the first address bumps may be twice the number of the second address bumps. For another example, the plurality of first connection bumps 500 and the plurality of second connection bumps 702 may include first command bumps and second command bumps, respectively, that are connected to command pads of the plurality of first semiconductor chips 100, 200 and 300, and the number of the first command bumps may be twice the number of the second command bumps.

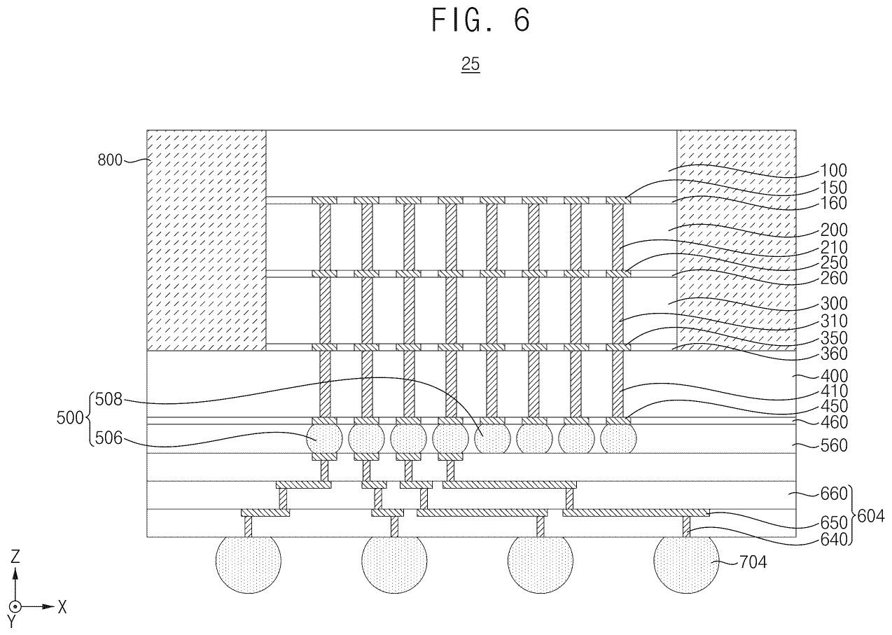

Referring to FIG. 6, a semiconductor package 25 may include a plurality of first semiconductor chips 100, 200 and 300, a second semiconductor chip 400, a plurality of first connection bumps 500, a redistribution layer 604 and a plurality of second connection bumps 704. The semiconductor package 25 may further include a plurality of connection structures 150, 250, 350 and 450, a plurality of insulating layers 160, 260, 360, 460 and 560, and an encapsulant 800.

The semiconductor package 25 may be substantially the same as the semiconductor package 10 of FIG. 1, except that configurations of the redistribution layer 604 and the plurality of second connection bumps 704 are partially changed. The redistribution layer 604 and the plurality of second connection bumps 704 may be similar to the redistribution layer 602 and the plurality of second connection bumps 702 in FIG. 5, respectively, and thus redundant descriptions thereof may be omitted.

In some example embodiments, the number of the plurality of second connection bumps 704 may be less than the number of the plurality of first connection bumps 500. For example, the number of the plurality of first connection bumps 500 may be twice the number of the plurality of second connection bumps 704.

In some example embodiments, the plurality of connection bumps 500 may include first connection bumps 506, which may be respectively and electrically connected to the plurality of second connection bumps 704 via the redistribution layer 604. The plurality of connection bumps 500 may include second connection bumps 508, which may be floated without electrical connections with the plurality of second connection bumps 704. The redistribution layer 604 may be implemented to respectively and electrically connect the first connection bumps 506 of the plurality of first connection bumps 500 with the plurality of second connection bumps 704. Thus, as shown in FIG. 6, the number of connection bumps 500 may be eight, and the first connection bumps 506 may include the first four connection bumps 506 that are respectively and electrically connected to the second connection bumps 704, and the second four connection bumps 508 may be floated without electrical connections with the plurality of second connection bumps 704.

In some example embodiments, the first connection bumps 506 of the plurality of first connection bumps 500 may be connection bumps of the left half among the plurality of first connection bumps 500, and the second connection bumps 508 of the plurality of first connection bumps 500 may be connection bumps of the right half among the plurality of first connection bumps 500.

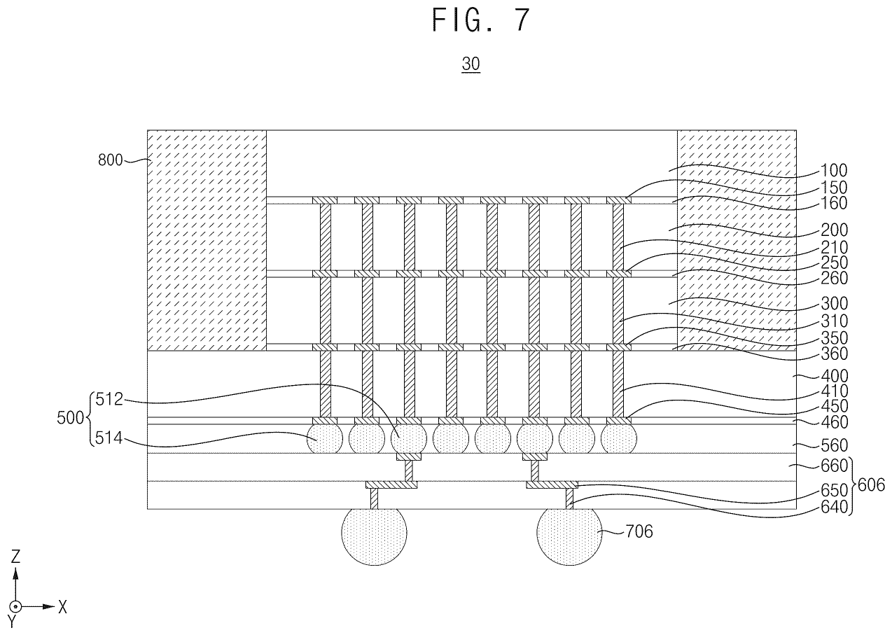

Referring to FIG. 7, a semiconductor package 30 may include a plurality of first semiconductor chips 100, 200 and 300, a second semiconductor chip 400, a plurality of first connection bumps 500, a redistribution layer 606 and a plurality of second connection bumps 706. The semiconductor package 25 may further include a plurality of connection structures 150, 250, 350 and 450, a plurality of insulating layers 160, 260, 360, 460 and 560, and an encapsulant 800.

The semiconductor package 30 may be substantially the same as the semiconductor package 10 of FIG. 1, except that configurations of the redistribution layer 606 and the plurality of second connection bumps 706 are partially changed. The redistribution layer 606 and the plurality of second connection bumps 706 may be similar to the redistribution layers 602 and 604 and the plurality of second connection bumps 702 and 704 in FIGS. 5 and 6, respectively, and thus redundant descriptions thereof may be omitted.

In some example embodiments, the number of the plurality of second connection bumps 706 may be less than the number of the plurality of first connection bumps 500. For example, the number of the plurality of first connection bumps 500 may be four times the number of the plurality of second connection bumps 706. In other words, the number of the plurality of second connection bumps 706 may be a quarter of the number of the plurality of first connection bumps 500.

In some example embodiments, the plurality of connection bumps 500 may include first connection bumps 512, which may be respectively and electrically connected to the plurality of second connection bumps 706 via the redistribution layer 606. The plurality of connection bumps 500 may include second connection bumps 514, which may be floated without electrical connections with the plurality of second connection bumps 706. The redistribution layer 606 may be implemented to respectively and electrically connect the first connection bumps 512 of the plurality of first connection bumps 500 with the plurality of second connection bumps 706. That is, as shown in FIG. 7, the number of second connection bumps 706 is two. The number of first connection bumps 512 may be two, and the two first connection bumps 512 may be respectively and electrically connected to the two second connection bumps of the plurality of connection bumps 706. The number of second connection bumps 514 may be six, and these connection bumps 514 may be floated without electrical connections with the plurality of second connection bumps 706.

In the example embodiments shown in FIGS. 5, 6 and 7, a number of first connection bumps and a number of second connection bumps of the plurality of first connection bumps 500, as well as a number of connection bumps of the plurality of second connection bumps 700, 702, 704 and 706 are shown with specific numbers, but these depictions are exemplary and not exclusive. One of ordinary skill in the art will understand from the disclosure herein that the number of connection bumps may be varied without departing from the scope of the disclosure.

In some example embodiments, the semiconductor package 30 may be a HBM device, and the plurality of first connection bumps 500 and the plurality of second connection bumps 706 may be electrically connected to data I/O pads of the plurality of first semiconductor chips 100, 200 and 300, which are DRAM chips. For example, the plurality of first connection bumps 500 may include first data I/O bumps, the plurality of second connection bumps 706 may include second data I/O bumps, and the number of the first data I/O bumps and the number of the second data I/O bumps may be 1024 and 256, respectively. However, example embodiments are not limited thereto. For example, the plurality of first connection bumps 500 and the plurality of second connection bumps 706 may include address bumps and/or command bumps.

Although FIGS. 5 and 6 illustrate examples where a half of the plurality of first connection bumps 500 are connected to the plurality of second connection bumps 702 and 704 and the remaining half of the plurality of first connection bumps 500 are not connected to the second connection bumps 702 and 704, and although FIG. 7 illustrates an example where a quarter of the plurality of first connection bumps 500 are connected to the second connection bumps 706 and the remaining three quarters of the plurality of first connection bumps 500 are not connected to the plurality of second connection bumps 706, example embodiments are not limited thereto. For example, among the plurality of first connection bumps 500, a first arbitrary number of connection bumps may be classified as a first group, the remainder of connection bumps may be classified as a second group, and then only the connection bumps of the first group may be electrically connected to the second connection bumps.

In some example embodiments, the first semiconductor chips 100, 200 and 300 and/or the second semiconductor chip 400 may include a component for driving only the first connection bumps 502, 506 and 512 that are electrically connected to the second connection bumps 702, 704 and 706, and for preventing from driving the first connection bumps 504, 508 and 514 that are not electrically connected to the second connection bumps 702, 704 and 706. For example, the first semiconductor chips 100, 200 and 300 and/or the second semiconductor chip 400 may further include a selection circuit for selecting a communication path. For example, when signals, data, etc. are to be transmitted and/or received via the first connection bumps 502, 506 and 512, the selection circuit may maintain a communication path. For example, when signals, data, etc. are to be transmitted and/or received via the first connection bumps 504, 508 and 514, the selection circuit may change a communication path to use the first connection bumps 502, 506 and 512 rather than the first connection bumps 504, 508 and 514. For example, the selection circuit may include a switch, a multiplexer, etc.

FIG. 8 is a perspective view illustrating a semiconductor package according to one or more example embodiments.

Referring to FIG. 8, a semiconductor package 900 may include a first semiconductor device (SD1) 910, a plurality of second semiconductor devices (SD2) 920 and a connection substrate 930.

The first semiconductor device 910 may control the overall operation of the semiconductor package 900. The plurality of second semiconductor devices 920 may be controlled by the first semiconductor device 910. The first semiconductor device 910 and the plurality of second semiconductor devices 920 may be mounted on the connection substrate 930. The first semiconductor device 910 and the plurality of second semiconductor devices 920 may be electrically connected to each other via the connection substrate 930.

Each of the plurality of second semiconductor devices 920 may be the semiconductor package according to example embodiments described with reference to FIGS. 1 through 7. For example, each of the plurality of second semiconductor devices 920 may include the first and second semiconductor chips that are different types of semiconductor chips and are stacked in the vertical direction. For example, each of the plurality of second semiconductor devices 920 may include the redistribution layer having the same width in the horizontal direction as the second semiconductor chip, the width being greater than the width of another semiconductor chip as is described above. For example, each of the plurality of second semiconductor devices 920 may include the first connection bumps between the second semiconductor chip and the redistribution layer, and the second connection bumps under the redistribution layer that are larger than the first connection bumps and are connected to the first connection bumps via the redistribution layer. The second semiconductor chip and the redistribution layer may have the same width in the horizontal direction, and thus the footprint of each of the plurality of second semiconductor devices 920 may not be increased and may be maintained. The second connection bumps that are relatively large in size and pitch may be used, and thus the electrical connection between each of the plurality of second semiconductor devices 920 and the connection substrate 930 may be relatively easily implemented.

In some example embodiments, the first semiconductor device 910 and the plurality of second semiconductor devices 920 may be different types of semiconductor devices. For example, the first semiconductor device 910 may be a logic semiconductor device that performs a data processing function, and the plurality of second semiconductor devices 920 may be memory semiconductor devices that perform a data storage function.

In some example embodiments, the connection substrate 930 may be or may include a connector implemented with a relatively lower price than a silicon interposer.

In some example embodiments, the connection substrate 930 may be a silicon-free interposer. For example, the connection substrate 930 may be a glass interposer. For example, the glass interposer may include through glass vias (TGVs) formed by penetrating a glass substrate, and the first semiconductor device 910 and the plurality of second semiconductor devices 920 may be electrically connected to each other through the TGVs.

In some example embodiments, the connection substrate 930 may be a package base substrate. For example, the connection substrate 930 may be a printed circuit board (PCB) substrate. For example, the PCB substrate may be a multilayer circuit board with vias and various circuits therein, and the first semiconductor device 910 and the plurality of second semiconductor devices 920 may be electrically connected to each other through the vias.

In some example embodiments, when the connection substrate 930 is a silicon-free interposer, the semiconductor package 900 may further include a package base substrate on which the connection substrate 930 including the first semiconductor device 910 and the plurality of second semiconductor devices 920 is mounted.

In a semiconductor system, a HBM device may be utilized when relatively high bandwidth is required.

In the semiconductor package 900 according to example embodiments, the first semiconductor device 910 and the plurality of second semiconductor devices 920 may be electrically connected to each other using the connection substrate 930 that is relatively cheap (e.g., the PCB substrate or the glass interposer) rather than the silicon interposer. The plurality of second semiconductor devices 920 may be implemented in the form of the semiconductor package according to example embodiments described with reference to FIGS. 1 through 7, and thus the second semiconductor devices 920 may have the same footprint as the conventional HBM device and have a larger bump size and larger bump pitch than the conventional HBM device. Accordingly, the semiconductor package 900 may be easily connected to the connection substrate 930, and the manufacturing cost of the semiconductor package 900 may be efficiently reduced.

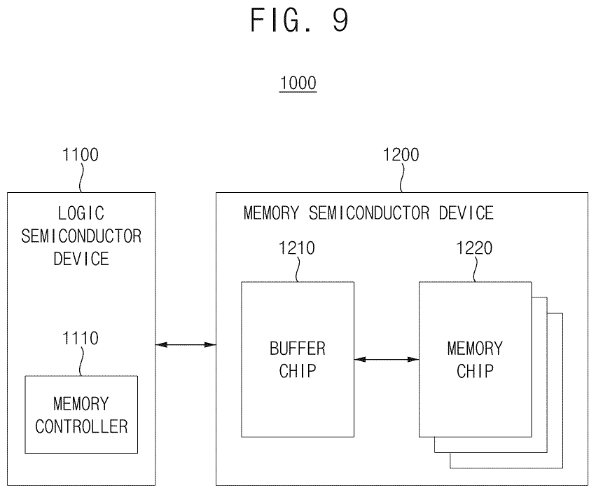

FIG. 9 is a block diagram illustrating a semiconductor system according to one or more example embodiments.

Referring to FIG. 9, a semiconductor system 1000 may include a logic semiconductor device 1100 and a memory semiconductor device 1200. The semiconductor system 1000 may correspond to the semiconductor package 900 of FIG. 8.

The logic semiconductor device 1100 may correspond to the first semiconductor device 910 in FIG. 8, and may include a memory controller 1110. For example, the logic semiconductor device 1100 may be or may include a device that operates as a host (e.g., a central processing unit (CPU), a graphic processing unit (GPU), a system-on-chip (SoC), a field programmable gate array (FPGA), an application specific integrated circuit (ASIC), etc.).

The memory semiconductor device 1200 may correspond to the second semiconductor device 920 in FIG. 8, and may include a buffer chip 1210 and a plurality of memory chips 1220. For example, the memory semiconductor device 1200 may correspond to the semiconductor package 10 of FIG. 1, and the buffer chip 1210 and the plurality of memory chips 1220 may correspond to the second semiconductor chip 400 and the plurality of first semiconductor chips 100, 200 and 300 in FIG. 1, respectively. For example, the memory semiconductor device 1200 may be a HBM device, and the plurality of memory chips 1220 may be DRAM chips.

The memory semiconductor device 1200 may be controlled by the memory controller 1110. For example, based on requests from the logic semiconductor device 1100, the memory controller 1110 may store (e.g., write or program) data into the memory semiconductor device 1200, or may retrieve (e.g., read or sense) data from the memory semiconductor device 1200. For example, the memory controller 1110 may transmit commands, addresses and control signals to the memory semiconductor device 1200, may exchange data signals with the memory semiconductor device 1200, and may provide power supply voltages to the memory semiconductor device 1200.

In a structure in which the plurality of memory chips 1220 are connected to one memory controller 1110, an output impedance of the memory controller 1110 may be relatively large, and thus a problem in which signals output from the memory controller 1110 do not properly reach or arrive the plurality of memory chips 1220 may occur. To solve the above-described problem, a structure in which the memory controller 1110 and the plurality of memory chips 1220 are connected by the buffer chip 1210 may be applied, employed or adopted, and thus the buffer chip 1210 may drive signals received from the memory controller 1110 and may appropriately transmit the signals to the memory chips 1220.

In some example embodiments, when only some of the first connection bumps 502, 506 and 512 are electrically connected to the second connection bumps 702, 704 and 706 as described with reference to FIGS. 5, 6 and 7, the buffer chip 1210 may include the selection circuit for selecting the communication path, and/or each of the plurality of memory chips 1220 may include the selection circuit.

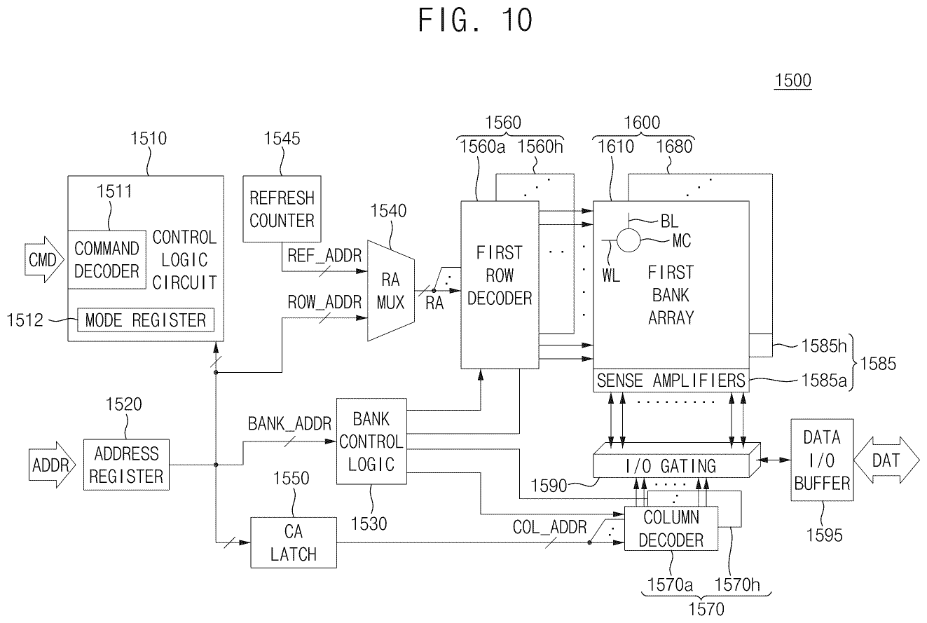

FIG. 10 is a block diagram illustrating an example of a memory chip included in a semiconductor system according to one or more example embodiments.

Referring to FIG. 10, a memory chip 1500 may include a control logic circuit 1510, an address register 1520, a bank control logic circuit 1530, a row address multiplexer 1540, a refresh counter 1545, a column address latch 1550, a row decoder 1560, a column decoder 1570, a memory cell array 1600, a sense amplifier unit 1585, an I/O gating circuit 1590 and a data I/O buffer 1595. For example, the memory chip 1500 may be one of various volatile memory chips such as a DRAM chip.

The memory cell array 1600 may include first to eighth bank arrays 1610 to 1680 (e.g., first to eighth bank arrays 1610 to 1680). The row decoder 1560 may include first to eighth bank row decoders 1560a to 1560h connected respectively to the first to eighth bank arrays 1610 to 1680. The column decoder 1570 may include first to eighth bank column decoders 1570a to 1570h connected respectively to the first to eighth bank arrays 1610 to 1680. The sense amplifier unit 1585 may include first to eighth bank sense amplifiers 1585a to 1585h connected respectively to the first to eighth bank arrays 1610 to 1680.

The first to eighth bank arrays 1610 to 1680, the first to eighth bank row decoders 1560a to 1560h, the first to eighth bank column decoders 1570a to 1570h, and the first to eighth bank sense amplifiers 1585a to 1585h may form first to eighth banks. Each of the first to eighth bank arrays 1610 to 1680 may include a plurality of wordlines WL, a plurality of bitlines BL, and a plurality of memory cells MC that are at intersections of the wordlines WL and the bitlines BL.

Although FIG. 10 illustrates the memory chip 1500 including eight banks (and eight bank arrays, eight row decoders, and so on), the memory chip 1500 may include any number of banks (for example, one, two, four, eight, sixteen, or thirty two banks, or any number therebetween one and thirty two, etc.).

The address register 1520 may receive the address ADDR including a bank address BANK_ADDR, a row address ROW_ADDR, and a column address COL_ADDR from a memory controller (e.g., the memory controller 1110 in FIG. 9) that is located outside the memory chip 1500. The address register 1520 may provide the received bank address BANK_ADDR to the bank control logic circuit 1530, may provide the received row address ROW_ADDR to the row address multiplexer 1540, and may provide the received column address COL_ADDR to the column address latch 1550.

The bank control logic circuit 1530 may generate bank control signals in response to the bank address BANK_ADDR. One of the first to eighth bank row decoders 1560a to 1560h corresponding to the bank address BANK_ADDR may be activated in response to the bank control signals, and one of the first to eighth bank column decoders 1570a to 1570h corresponding to the bank address BANK_ADDR may be activated in response to the bank control signals.

The row address multiplexer 1540 may receive the row address ROW_ADDR from the address register 1520, and may receive a refresh row address REF_ADDR from the refresh counter 1545. The row address multiplexer 1540 may selectively output the row address ROW_ADDR or the refresh row address REF_ADDR as a row address RA. The row address RA that is output from the row address multiplexer 1540 may be applied to the first to eighth bank row decoders 1560a to 1560h.

The activated one of the first to eighth bank row decoders 1560a to 1560h may decode the row address RA that is output from the row address multiplexer 1540, and may activate in the corresponding bank array a wordline WL corresponding to the row address RA. For example, the activated bank row decoder may generate a wordline driving voltage, and may apply the wordline driving voltage to the wordline WL corresponding to the row address RA.

The column address latch 1550 may receive the column address COL_ADDR from the address register 1520, and may temporarily store the received column address COL_ADDR. In some example embodiments, in a burst mode, the column address latch 1550 may generate column addresses that increment from the received column address COL_ADDR. The column address latch 1550 may apply the temporarily stored or generated column address to the first to eighth bank column decoders 1570a to 1570h.

The activated one of the first to eighth bank column decoders 1570a to 1570h may decode the column address COL_ADDR that is output from the column address latch 1550, and may control the I/O gating circuit 1590 to output data corresponding to the column address COL_ADDR.

The I/O gating circuit 1590 may include circuitry configured to gate input/output data. The I/O gating circuit 1590 may further include read data latches configured to store data that is output from the first to eighth bank arrays 1610 to 1680, and may also include write control devices for writing data to the first to eighth bank arrays 1610 to 1680.

Data DAT read from one of the first to eighth bank arrays 1610 to 1680 may be sensed by a sense amplifier connected to the one bank array from which the data DAT is to be read, and may be stored in the read data latches. The data DAT stored in the read data latches may be provided to the memory controller via the data I/O buffer 1595. Data DAT to be written in one of the first to eighth bank arrays 1610 to 1680 may be provided to the I/O gating circuit 1590 via the data I/O buffer 1595 from the memory controller, and the I/O gating circuit 1590 may write the data DAT in the one bank array through the write drivers.

The control logic circuit 1510 may control operations of the memory chip 1500. For example, the control logic circuit 1510 may generate control signals for the memory chip 1500 to perform the write operation and/or the read operation. The control logic circuit 1510 may include a command decoder 1511 that decodes a command CMD received from the memory controller, and a mode register 1512 that sets an operation mode of the memory chip 1500. In some example embodiments, operations described herein as being performed by the control logic circuit 1510 may be performed by processing circuitry. For example, the command decoder 1511 may generate the control signals corresponding to the command CMD by decoding a write enable signal, a row address strobe signal, a column address strobe signal, a chip selection signal, etc.

Command pads for receiving the command CMD, address pads for receiving the addresses ADDR, and data pads for exchanging the data DAT may be electrically connected to the first connection bumps 500 and the second connection bumps 700 in FIG. 1.

In some example embodiments, when only some of the first connection bumps 502, 506 and 512 are electrically connected to the second connection bumps 702, 704 and 706 as described with reference to FIGS. 5, 6 and 7, and when each memory chip includes the selection circuit for selecting the communication path, the selection circuit may be connected to the data pads or to the command/address pads.

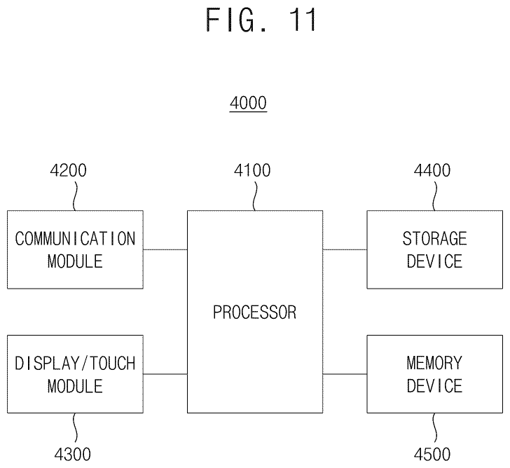

FIG. 11 is a block diagram illustrating an electronic system according to one or more example embodiments.

Referring to FIG. 11, an electronic system 4000 includes at least one processor 4100, a communication module 4200, a display/touch module 4300, a storage device 4400 and a memory device 4500. For example, the electronic system 4000 may be any mobile system or any computing system.

The processor 4100 may control operations of the electronic system 4000. For example, the processor 4100 may execute an operating system and at least one application to provide an internet browser, games, videos, or the like. The communication module 4200 may be controlled by the processor 4100 and may perform wireless or wire communications with an external system. The display/touch module 4300 may display data processed by the processor 4100 and/or may receive data through a touch panel. The storage device 4400 may store user data. The memory device 4500 may temporarily store data used for processing operations of the electronic system 4000.

At least portions of the electronic system 4000 may be implemented in the form of the semiconductor package according to example embodiments. For example, the memory device 4500 may be implemented in the form of the semiconductor package according to example embodiments described with reference to FIGS. 1 through 7, and the processor 4100 and the memory device 4500 may be implemented in the form of the semiconductor package according to example embodiments described with reference to FIG. 8.

Although the semiconductor package that includes the logic semiconductor device and the memory semiconductor devices and has a 2.5-dimensional (2.5D) stacked structure is described with reference to FIG. 8, example embodiments are not limited thereto.

In some example embodiments, the semiconductor package according to example embodiments may be a lower semiconductor package or an upper semiconductor package constituting a semiconductor package of a package on package (PoP) type.

In some example embodiments, the semiconductor package according to example embodiments may be a semiconductor package having a three-dimensional (3D) stacked structure. In the semiconductor package having the 3D stacked structure, a distance between semiconductor devices (or chips) may be reduced by vertically stacking several semiconductor devices that are the same as or different from each other. For example, the semiconductor devices may have respective through electrodes, thereby shortening a time taken for data transmission to other semiconductor devices. The semiconductor package having the 3D stacked structure may include various types of semiconductor devices freely arranged therein, thereby increasing a speed of data processing between the semiconductor devices.

In some example embodiments, the semiconductor package according to example embodiments may be a wafer level package (WLP), and may be a fan-out wafer level package (FOWLP) or a fan-in wafer level package (FIWLP) where a package connection terminal or an external connection pad is located outside a region of a semiconductor chip or inside the region of the semiconductor chip.

In some example embodiments, the semiconductor package according to example embodiments may be a chip-last fan-out semiconductor package in which an interposer or a connection substrate is formed, and then at least one semiconductor device is mounted on the interposer or the connection substrate. In other example embodiments, the semiconductor package according to example embodiments may be a chip-first semiconductor package in which at least one semiconductor device is mounted on a tape, a periphery of the semiconductor device is surrounded with a molding layer, and then an interposer or a connection substrate is connected to the semiconductor device. In some example embodiments, the semiconductor package according to example embodiments may be a fan-out panel level package (FOPLP).

In some example embodiments, the semiconductor package according to example embodiments may include a plurality of semiconductor devices, and the semiconductor package according to example embodiments may be a system-in-package (SIP) in which the plurality of semiconductor devices of different types are electrically connected to each other to operate as a single system.

The example embodiments may be applied to various electronic devices and systems that include the semiconductor packages. For example, the example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

The foregoing is illustrative of example embodiments and is not to be construed as limiting thereof. Although some example embodiments have been described, those skilled in the art will readily appreciate that many modifications are possible in the example embodiments without materially departing from the novel teachings and advantages of the example embodiments. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A semiconductor package comprising:
a plurality of first semiconductor chips sequentially stacked in a vertical direction, at least one of the plurality of first semiconductor chips comprising a plurality of first through electrodes connecting the plurality of first semiconductor chips to each other, each of the plurality of first semiconductor chips having a first width in a horizontal direction;
a second semiconductor chip under the plurality of first semiconductor chips, the second semiconductor chips comprising a plurality of second through electrodes connecting the second semiconductor chip to the plurality of first semiconductor chips, the second semiconductor chip having a second width in the horizontal direction that is greater than the first width;
a redistribution layer under the second semiconductor chip, the redistribution layer having a third width in the horizontal direction that is substantially equal to the second width;
a plurality of first connection bumps between the second semiconductor chip and the redistribution layer, and connecting the second semiconductor chip with the redistribution layer, each of the plurality of first connection bumps having a first size; and
a plurality of second connection bumps under the redistribution layer, and connecting the redistribution layer with an external device, each of the plurality of second connection bumps having a second size that is greater than the first size.

2. The semiconductor package of claim 1, wherein a first distance between two adjacent first connection bumps of the plurality of first connection bumps is less than a second distance between two adjacent second connection bumps of the plurality of second connection bumps.

3. The semiconductor package of claim 1, wherein a number of the plurality of second connection bumps is less than a number of the plurality of first connection bumps.

4. The semiconductor package of claim 3, wherein the number of the plurality of first connection bumps is twice the number of the plurality of second connection bumps.

5. The semiconductor package of claim 3, wherein the number of the plurality of first connection bumps is four times the number of the plurality of second connection bumps.

6. The semiconductor package of claim 1, wherein a first number of first connection bumps among the plurality of first connection bumps are respectively connected to a second number of second connection bumps among the plurality of second connection bumps via the redistribution layer, and
wherein a third number of first connection bumps among the plurality of first connection bumps are floated without connections with the plurality of second connection bumps.

7. The semiconductor package of claim 1, wherein a number of the plurality of second connection bumps is equal to a number of the plurality of first connection bumps.

8. The semiconductor package of claim 7, wherein the plurality of first connection bumps are respectively connected to the plurality of second connection bumps via the redistribution layer.

9. The semiconductor package of claim 1, wherein, in a plan view, the plurality of first connection bumps are arranged adjacent to a center of the semiconductor package, and the plurality of second connection bumps are uniformly arranged around the semiconductor package.

10. The semiconductor package of claim 1, further comprising:
an encapsulant encapsulating the plurality of first semiconductor chips and the second semiconductor chip.

11. The semiconductor package of claim 10, wherein the encapsulant directly contacts side surfaces of the plurality of first semiconductor chips and directly contacts at least a portion of an upper surface of the second semiconductor chip.

12. The semiconductor package of claim 1, wherein the plurality of first semiconductor chips comprises an uppermost first semiconductor chip and a remaining number of first semiconductor chips,
wherein the plurality of first through electrodes penetrate the remaining number of first semiconductor layer, and
wherein the plurality of second through electrodes penetrate the second semiconductor chip.

13. The semiconductor package of claim 12, wherein none of the plurality of first through electrodes penetrate the uppermost first semiconductor chip among the plurality of first semiconductor chips.

14. The semiconductor package of claim 1, wherein the plurality of first semiconductor chips and the second semiconductor chip are different types of semiconductor chips.

15. The semiconductor package of claim 14, wherein the plurality of first semiconductor chips comprise dynamic random access memory (DRAM) chips configured to store data,
wherein the second semiconductor chip comprises a buffer chip configured to control operations of the DRAM chips, and
wherein the semiconductor package is a high bandwidth memory (HBM) device.

16. A semiconductor package comprising:
a first semiconductor device;
a plurality of second semiconductor devices, wherein the first semiconductor device is configured to control the plurality of second semiconductor devices; and
a connection substrate on which the first semiconductor device and the plurality of second semiconductor devices are provided,
wherein each of the plurality of second semiconductor devices comprises:
a plurality of first semiconductor chips sequentially stacked in a vertical direction, at least one of the plurality of first semiconductor chips comprising a plurality of first through electrodes connecting the plurality of first semiconductor chips to each other, each of the plurality of first semiconductor chips having a first width in a horizontal direction;
a second semiconductor chip under the plurality of first semiconductor chips, the second semiconductor chips comprising a plurality of second through electrodes connecting the second semiconductor chip to the plurality of first semiconductor chips, the second semiconductor chip having a second width in the horizontal direction that is greater than the first width;
a redistribution layer under the second semiconductor chip, the redistribution layer having a third width in the horizontal direction that is substantially equal to the second width;
a plurality of first connection bumps between the second semiconductor chip and the redistribution layer, and connecting the second semiconductor chip with the redistribution layer, each of the plurality of first connection bumps having a first size; and
a plurality of second connection bumps under the redistribution layer, and connecting the redistribution layer with an external device, each of the plurality of second connection bumps having a second size that is greater than the first size.

17. The semiconductor package of claim 16, wherein the connection substrate comprises a silicon-free interposer.

18. The semiconductor package of claim 16, wherein the connection substrate comprises a printed circuit board (PCB) substrate.

19. The semiconductor package of claim 16, wherein the first semiconductor device comprises a logic semiconductor device configured to perform a data processing function, and
wherein the plurality of second semiconductor devices comprise memory semiconductor devices configured to perform a data storage function.

20. (canceled)

21. A semiconductor package comprising:
a first dynamic random access memory (DRAM) chip having a first width in a horizontal direction;
a plurality of second DRAM chips sequentially stacked in a vertical direction under the first DRAM chip, at least one of the plurality of second DRAM chips comprising a plurality of first through electrodes connecting the plurality of first semiconductor chips to each other and to the first DRAM chip, each of the plurality of second DRAM chips having a second width in the horizontal direction that is substantially equal to the first width;
a buffer chip under the plurality of second DRAM chips, the buffer chip comprising a plurality of second through electrodes connecting to the first DRAM chip and the plurality of second DRAM chips, the buffer chip having a third width in the horizontal direction that is greater than the first width;
a redistribution layer under the buffer chip, the redistribution layer having a fourth width in the horizontal direction that is substantially equal to the third width;
a plurality of first connection bumps between the buffer chip and the redistribution layer, and connected to the plurality of second through electrodes and the redistribution layer, each of the plurality of first connection bumps having a first size;
a plurality of second connection bumps under the redistribution layer, and connected to the redistribution layer, each of the plurality of second connection bumps having a second size that is greater than the first size; and
an encapsulant encapsulating the first DRAM chip, the plurality of second DRAM chips and the buffer chip, the encapsulant covering side surfaces of the first DRAM chip, side surfaces of the plurality of second DRAM chips, and at least a portion of an upper surface of the buffer chip,
wherein a number of the plurality of second connection bumps is less than a number of the plurality of first connection bumps,
wherein a first number of first connection bumps among the plurality of first connection bumps are respectively connected to a second number of second connection bumps among the plurality of second connection bumps via the redistribution layer,
wherein the first DRAM chip, the plurality of second DRAM chips and the buffer chip are electrically connected to an external device by the first number of first connection bumps, the redistribution layer and the second number of second connection bumps, and
wherein a second number of first connection bumps among the plurality of first connection bumps are floated without connections with the redistribution layer, the plurality of second connection bumps and the external device.
